(19) United States
(12) Patent Application Publication
(10) Pub. No.: US 2008/0169521 A1
(43) Pub. Date: Jul. 17, 2008

(54) MEMS structure using carbon dioxide and method of fabrication

(75) Inventors: John S. Foster, Santa Barbara, CA (US); Alok Paranjpye, Santa Barbara, CA (US); Jeffery F. Summers, Santa Barbara, CA (US); Douglas L. Thompson, Santa Barbara, CA (US)

Correspondence Address: Jaquelin K. Spong, Apt. A1, 2246 Mohegan Drive, Falls Church, VA, 22043, US

(73) Assignee: Innovative Micro Techonology, Goleta, CA (US)

(21) Appl. No.: 11/652,631

(22) Filed: Jan. 12, 2007

(51) Int. Cl. H01L 29/84; H01L 21/56; H01L 21/67

(52) U.S. Cl. 257/415; 438/51; 29/25.01; 257/E29.324; 257/E21.502

(57) ABSTRACT

A MEMS device is encapsulated in a carbon dioxide environment, which effectively insulates the MEMS device against arcing in high voltage applications. The carbon dioxide environment may have a pressure of between about 0.2 atm and about 4 atm. Carbon dioxide is shown to be more effective than other insulating gases such as sulfur hexafluoride in preventing arcing for applications having dimensions on the order of microns.

### CROSS REFERENCE TO RELATED APPLICATIONS

Not applicable.

### STATEMENT REGARDING FEDERALLY SPONSORED RESEARCH

Not applicable.

### STATEMENT REGARDING MICROFICHE APPENDIX

Not applicable.

### BACKGROUND

This invention relates to MEMS structures for high voltage applications. In particular, this invention relates to a system and method for using carbon dioxide as a preferred environment for a high voltage MEMS switch.

Telephone and other communications devices require a large number of switches to form the connections to activate the telephone calls. In general, the switches may be configured to connect any input line to any output line, and may therefore form a “cross connect.” In order to miniaturize the component, the individual switches, of which there may be on the order of hundreds or even thousands, may be made using microelectromechanical systems, or MEMS. One example of a MEMS switch usable for making a telephone cross connect is a thermally-driven actuator, which is heated by the application of a current, and which then drives a passive beam to which it is tethered. By applying a current to the driving arm of the switch, the driving arm heats up, and bends in a particular direction about an anchor point. This motion may establish or discontinue contact with another arm of the switch, for example. Therefore, the plurality of switches may be activated by delivering current to each arm of the switch, in order to heat the switch and drive it to its closed (or open) position.

The voltage load on a telephone network can exceed 400 V under certain extreme conditions, e.g. a lightning strike. Also, because of the large number of lines being connected by the cross connect, the cross connect may be required to carry an ampere or more of current. Because of these current and voltage requirements, many telephone switches are hermetically enclosed in insulating gas environments which inhibit arcing between the high voltage lines. Such insulating gases may include, for example, sulfur hexafluoride (SF₆) or freons CCl₂F₂ or C₂Cl₂F₄. The use of such insulating gases may increase the breakdown voltage compared to that of air by about a factor of three.

The insulating gas environment may be contained around the device by etching a plurality of device cavities in a lid wafer deep enough to allow clearance for the movement of the MEMS thermally actuated switch device. The lid wafer is then aligned with the device wafer supporting the switches, and the lid wafer is bonded to the device wafer with a hermetic, i.e. non-leaking adhesive.

### SUMMARY

Typically, insulating gases such as sulfur hexafluoride are expensive, and may be environmentally damaging, as they are suspected of contributing to the greenhouse effect, whereby radiation is absorbed from the sun but is then trapped by reflective gas layers in the Earth's atmosphere, thus raising the temperature of the Earth.

Systems and methods are described here which use carbon dioxide (CO₂) as an insulating gas in MEMS applications, particularly high voltage switching applications such as the telephone switch described above. Carbon dioxide is shown to have an unexpectedly high breakdown voltage compared to sulfur hexafluoride. Furthermore, the carbon dioxide may be less reactive than other gases such as sulfur hexafluoride with the other components of the MEMS device. Carbon dioxide is also cheaper, and is significantly less environmentally damaging.

The carbon dioxide may be sealed beneath a lid wafer affixed to the MEMS device wafer, with a hermetic adhesive. Such an adhesive may be, for example, a metal alloy film. The carbon dioxide environment may be provided at a pressure of between about 0.2 atm to about 4 atm, which may provide a breakdown voltage in excess of 450 V to the enclosed switch. This performance may substantially exceed that of sulfur hexafluoride, which may provide a breakdown voltage in this application of only about 425 V.

Accordingly, an encapsulated MEMS device is described, which comprises a lid wafer with at least one device cavity formed therein, a device wafer supporting at least one MEMS device, a hermetic seal coupling the lid wafer to the device wafer, and a preferred environment sealed in the at least one device cavity by the hermetic seal, wherein the preferred environment comprises substantially pure carbon dioxide.

These and other features and advantages are described in, or are apparent from, the following detailed description.

### BRIEF DESCRIPTION OF THE DRAWINGS

Various exemplary details are described with reference to the following figures, wherein:

FIG. 1 is a plan view of an exemplary embodiment of a MEMS switch;

FIG. 2 is cross sectional view of a hermetic MEMS switch structure encapsulated in a carbon dioxide environment;

FIG. 3 is plot of the experimental high voltage breakdown data for carbon dioxide;

FIG. 4 is a plot of the experimental high voltage breakdown data for sulfur hexafluoride;

FIG. 5 is a published Paschen curve showing the high voltage breakdown limit for carbon dioxide as a function of gas pressure and electrode spacing;

FIG. 6 is a published Paschen curve showing the high voltage breakdown limit for sulfur hexafluoride as a function of gas pressure and electrode spacing;

FIG. 7 is a published modified Paschen curve for a generalized gas showing behavior at small gap spacings;

FIG. 8 is an exemplary first step in the formation of the switch structure of the hermetic switch;

FIG. 9 is an exemplary second step in the formation of the switch structure of the hermetic switch;

FIG. 10 is an exemplary third step in the formation of the switch structure of the hermetic switch;

FIG. 11 is an exemplary fourth step in the formation of the switch structure of the hermetic switch;

FIG. 12 is an exemplary first step in the formation of the cap wafer for the hermetic switch;

FIG. 13 is an exemplary second step in the formation of the cap wafer for the hermetic switch;

FIG. 14 is an exemplary third step in the formation of the cap wafer for the hermetic switch;

FIG. 15 is an exemplary fourth step in the formation of the cap wafer for the hermetic switch;

FIG. 16 is an illustration of a completed exemplary hermetic switch; and

### DETAILED DESCRIPTION

In the systems and methods described herein, a hermetic MEMS switch device is described which may be particularly suited for high voltage telephone switches. The hermetic device may enclose carbon dioxide as the insulating gas in the switch environment. Although the systems and methods are described with respect to a telephone switch embodiment, it should be understood that this embodiment is exemplary only, and that the systems and methods may be applied to any MEMS device, particularly those carrying high currents and/or high voltages. The term “MEMS device” should be understood to mean any device generally not including transistors, which are fabricated using MEMS processes and having characteristic dimensions on the order of several hundred microns or less. In such devices, the distance between a high voltage terminal and a low voltage terminal may be less than about 10 μm. The two terminals may generally be electrically insulated from one another, and separated by the small gap filled with the ambient gas that may be hermetically sealed with the MEMS device. Accordingly, the electrical characteristics of this gas are primary factors in determining the voltages that the device can safely handle. The systems and methods presented here describe a novel MEMS device which is encapsulated with substantially pure carbon dioxide as the insulating gas.

Furthermore, the systems and methods are described with respect to a particular design of MEMS switch. However, it should be understood that this particular design of MEMS switch is exemplary only, and that the systems and methods described herein can be applied to any number of alternative designs of MEMS switches or other devices.

It should also be understood that in the figures which follow, the various dimensions are not necessarily drawn to scale, but instead are intended to illustrate the important aspects of the features.

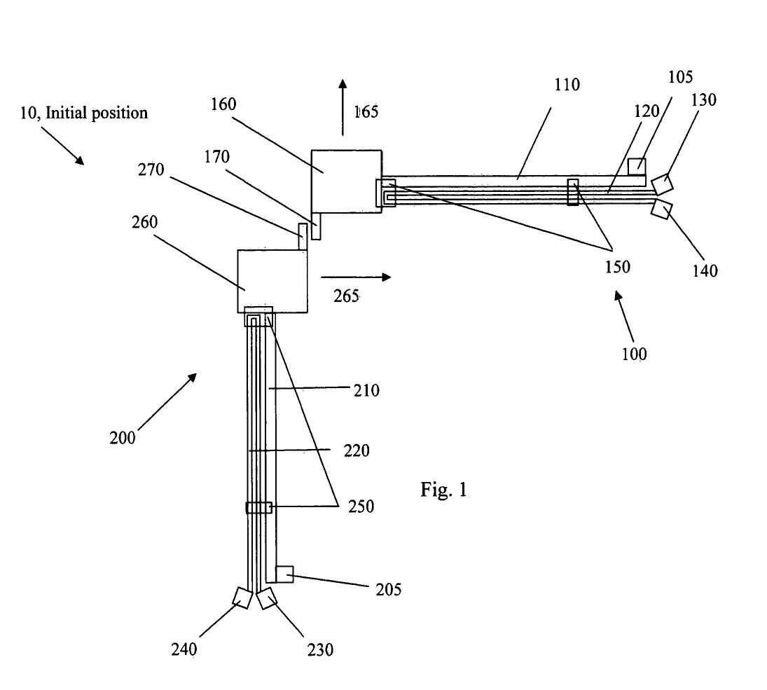

FIG. 1 shows an example of a MEMS thermal switch, which may be used to switch a telephone signal input on an input line to input terminal 105 to an output terminal 205. The thermal switch 10 includes two cantilevered structures, 100 and 200. Each cantilevered structure 100 and 200 contains a passive beam 110 and 210, respectively, which pivot about fixed anchor points 155 and 255, respectively. A conductive drive circuit 120 and 220, is coupled to each passive beam 110 and 210 by a plurality of dielectric tethers 150 and 250, respectively.

When a voltage is applied between terminals 130 and 140, a current is driven through conductive circuit 120. The Joule heating generated by the current causes the circuit 120 to expand relative to the unheated passive beam 110. Since the circuit is coupled to the passive beam 110 by the dielectric tether 150, the expanding conductive circuit drives the passive beam in the upward direction 165.

In addition, applying a voltage between terminals 230 and 240 causes heat to be generated in circuit 220, which drives passive beam 210 in the direction 265 shown in FIG. 1. Therefore, one beam 100 moves in direction 165 and the other beam 200 moves in direction 265. These movements may be used to open and close a set of contacts located on contact flanges 170 and 270, each in turn located on tip members 160 and 260, respectively, at the distal ends of passive beams 110 and 210.

To begin the closing sequence, tip member 160 and contact flange 170 are moved about 10 μm in the direction 165 by the application of a voltage between terminals 130 and 140. Then, tip member 260 and contact flange 270 are moved about 17 μm in the direction 265 by application of a voltage between terminals 230 and 240. Afterwards, tip member 160 and contact flange 170 are brought back to their initial position by removing the voltage between terminals 130 and 140. This stops current from flowing and cools the cantilever 100 and it returns to its original position. Finally, tip member 260 and contact flange 270 are brought back to nearly their original position by removing the voltage between terminals 230 and 240. However, in this position, tip member 160 and contact flange 170 prevent tip member 260 and contact flange 270 from moving completely back to their original positions, because of the mechanical interference between contact flanges 170 and 270. In this position, contact between the faces of contact flanges 170 and 270 provides an electrical connection between cantilevered structures 100 and 200, such that the electrical switch is closed. Opening the electrical switch is accomplished by reversing the movements just described.

The switch shown in FIG. 1 may be encapsulated by bonding a substrate supporting a plurality of switches 10 to a lid wafer with an adhesive which forms a hermetic seal. The encapsulation may enclose a preferred environment with the switch 10, which may be substantially pure carbon dioxide, as discussed further below. The term “substantially pure” carbon dioxide should be understood to mean that carbon dioxide makes up at least 90% of the gaseous material, the remainder being other impurity gases such as nitrogen or oxygen. In one exemplary embodiment, the preferred environment consists of at least 95% carbon dioxide, and more preferably about 97% carbon dioxide, with the remaining 3% consisting of water (H₂O) and oxygen (O₂). The substantially pure carbon dioxide does not react with or corrode the dielectric tethers 150 and 250, which tether the conductive drive circuits 120 and 220 to the passive beams 110 and 210, respectively.

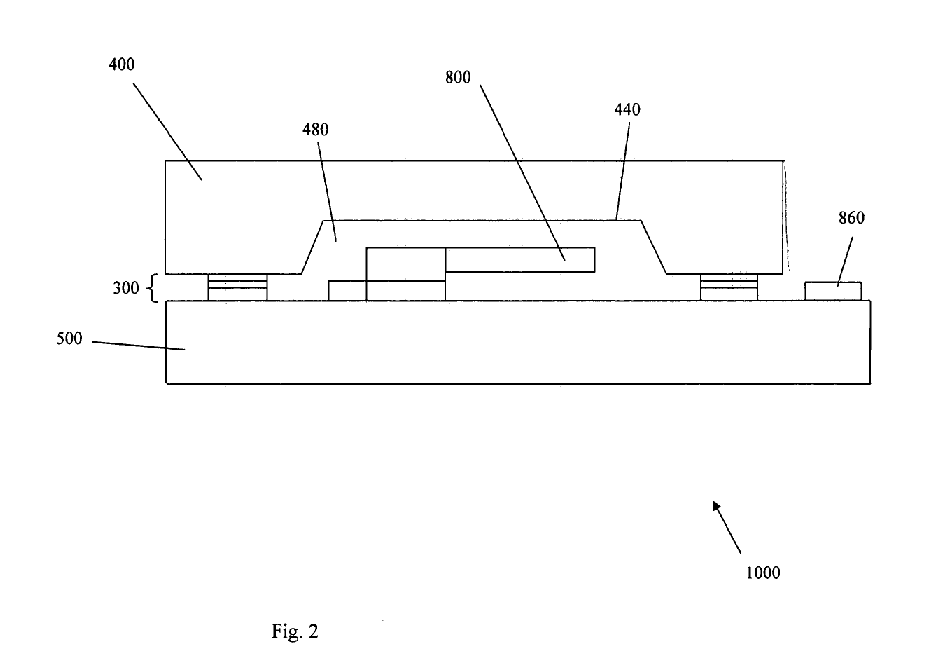

FIG. 2 is a cross sectional side view of a hermetic switch device 1000, enclosed in a substantially pure carbon dioxide environment. Hermetic switch device 1000 includes a lid or cap wafer 400, which covers and seals the switch structure 800 in the carbon dioxide environment 480.

Although FIG. 2 shows the MEMS switch structure as only a generic cantilevered member 800, it should be understood that MEMS switch structure 800 may represent any of cantilevered beams 110, 210, 120, or 220 of MEMS thermal switch 10 illustrated in FIG. 1. It should also be understood that MEMS switch structure 800 may represent any of a number of MEMS devices other than switches using cantilevered beams, such as accelerometers or actuators. The systems and methods described here may also be applied the non-cantilevered MEMS devices, such as devices using diaphragms or doubly-supported beams, used for example, in MEMS resonators. The systems and methods described here may also be applied to devices fabricated using MEMS techniques, although having no moving parts, such as photonic crystals, infrared emitters and detectors. One such exemplary MEMS photonic crystal is described in U.S. patent application Ser. No. 11/605,312, incorporated by reference herein in its entirety. In fact, the term “MEMS devices” should be understood to mean any device generally not including transistors, which are fabricated using MEMS processes. Although only a single switch structure 800 is shown in FIG. 2, it should be understood that in actuality there may be far more switches, for example 96, enclosed under a single lid.

The lid or cap wafer 400 may be secured to the device substrate 500 by an alloy seal 300. The lid or cap wafer 400 may be a metal or semiconductor material, such as a silicon substrate, within which a cavity 440 is relieved to provide clearance for the switch structure 800. Alternatively, the lid or cap 400 may be a transparent glass plate, or it may be a ceramic. The lid or cap wafer 400 may thereby seal a carbon dioxide insulating environment 480 around the switch structure 800. The switch structure 800 may have been previously formed over a substrate 500 by, for example, the method described further below. The substrate 500 may be any convenient material, such as thermally oxidized silicon, which is widely used in semiconductor and MEMS processing, which may provide a fabrication plane for the switch structures 800. Although not shown in FIG. 2, hermetic switch device 1000 may also include electrical conductors which allow electrical access to the switch structure 800 from a point outside the hermetic cavity 440.

The maximum high voltage breakdown of a device is often measured in terms of a Paschen curve, which plots the breakdown voltage as a function of the product of the pressure and the distance between the electrodes. Depending on the exact configuration of the switch device 1000, the device may be required to withstand a voltage difference of about 450 to about 500 volts between the two passive beams 110 and 210 which form the signal switch. Accordingly, to test the high voltage breakdown of switch device 1000, a high voltage, for example 450 volts, may be applied to passive cantilevered beam 110 and zero volts applied to passive beam 210. Alternatively, the voltage may be applied differentially, by applying +225 volts to passive beam 110 and −225 volts to passive beam 210. The minimum distance between the cantilevered passive beam 110 and cantilevered passive beam 210 is about 3 μm. Accordingly, if a pressure of 1 atmosphere is sealed within the device cavity 240, the pressure×gap distance for the switch device is about 2.3 mm Hg-mm. The two terminals are then monitored to detect any current flowing between them, which would indicate that the gas environment has broken down and arcing is occurring. A number of switch structures 1000 may be made with carbon dioxide gas and another set made with a comparison reference gas, and the performance differences between the two sets is measured.

For example, to assess the relative effectiveness of the carbon dioxide environment, it will be compared to the performance of a commonly used gaseous insulator, sulfur hexafluoride (SF₆). Since SF₆ is known in the art as a high voltage insulating gas, a bonded wafer pair is made according to FIG. 2 and the device cavity is filled with SF₆ for one set of devices, and with CO₂ for another set of devices. The voltage between the terminals is ramped up until current flow is detected, and the voltage recorded at which this breakdown occurred. The performance of the two gases is then compared, and the results are summarized in Tables 1 and 2, below. Table 1 shows the results for a wafer pair bonded with CO₂ in the device cavity 480. Table 2 shows the results for a wafer pair bonded with SF₆ enclosed in the device cavity 480. Both Tables 1 and 2 show the population of devices which meet or exceed a given high voltage. For example, in Table 1 corresponding to the devices sealed in carbon dioxide, one-quarter of the devices failed at 450 volts, one-half of the devices failed at 450 volts, and 75% of devices failed at 460 volts. In contrast, in Table 2 corresponding to the devices sealed in sulfur hexafluoride, one-quarter of the devices failed at 410 volts, one-half of the devices failed at 430 volts, and 75% of the devices failed at 436 volts. Thus, there is substantially better performance for devices fabricated with carbon dioxide in the device cavity relative to devices formed with sulfur hexafluoride in the device cavity.

TABLE 1
High Voltage breakdown for CO₂

| Quantiles | | | Moments | |
|---|---|---|---|---|
| 100.0% | Maximum | 500.00 | Mean | 456.36364 |
| 99.5% | | 500.00 | Std Dev | 15.666989 |
| 97.5% | | 500.00 | Std Err Mean | 4.7237749 |
| 90.0% | | 492.00 | Upper 95% Mean | 466.88886 |
| 75.0% | Quartile | 460.00 | Lower 95% Mean | 445.83841 |
| 50.0% | Median | 450.00 | N | 11 |
| 25.0% | Quartile | 450.00 | | |
| 10.0% | | 442.00 | | |
| 2.5% | | 440.00 | | |
| 0.5% | | 440.00 | | |
| 0.0% | Minimum | 440.00 | | |

TABLE 2
High Voltage breakdown for SF₆

| Quantiles | | | Moments | |
|---|---|---|---|---|
| 100.0% | Maximum | 479.00 | Mean | 423.0202 |
| 99.5% | | 479.00 | Std Dev | 23.118585 |
| 97.5% | | 469.00 | Std Err Mean | 2.3235052 |
| 90.0% | | 450.00 | Upper 95% Mean | 427.63112 |
| 75.0% | Quartile | 436.00 | Lower 95% Mean | 418.40928 |
| 50.0% | Median | 430.00 | N | 99 |
| 25.0% | Quartile | 410.00 | | |
| 10.0% | | 390.00 | | |
| 2.5% | | 365.00 | | |
| 0.5% | | 330.00 | | |
| 0.0% | Minimum | 330.00 | | |

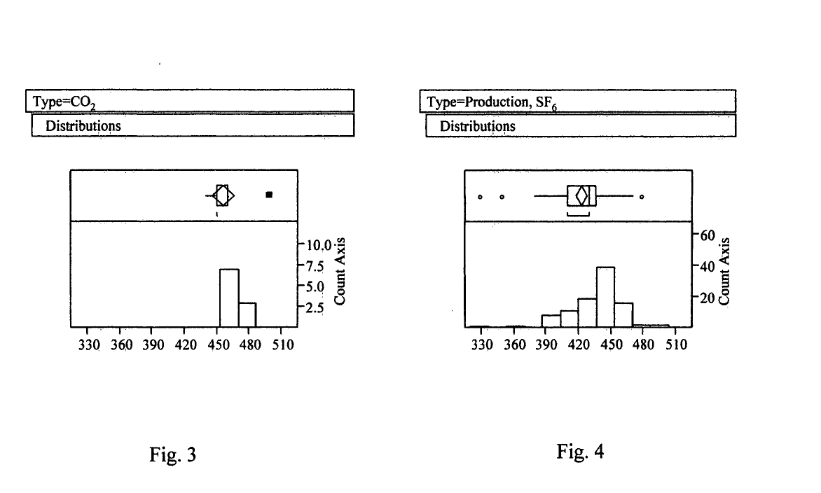

The data presented in Tables 1 and 2 are plotted graphically in FIGS. 3 and 4. FIG. 3 shows the data from Table 1, representing the performance of carbon dioxide as an insulating gas. The histograms correspond to the populations which do not arc at the applied voltage. FIG. 4 shows the data from Table 2, representing the performance of sulfur hexafluoride. As can be seen from FIGS. 3 and 4, the population for the carbon dioxide-filled devices is shifted to larger voltages, indicating better insulating performance than those of the sulfur hexafluoride. In fact, the mean value of the applied voltage (that voltage at which one-half of the population surpassed, and one-half of the population failed) is 456 volts for carbon dioxide and only 423 volts for sulfur hexafluoride.

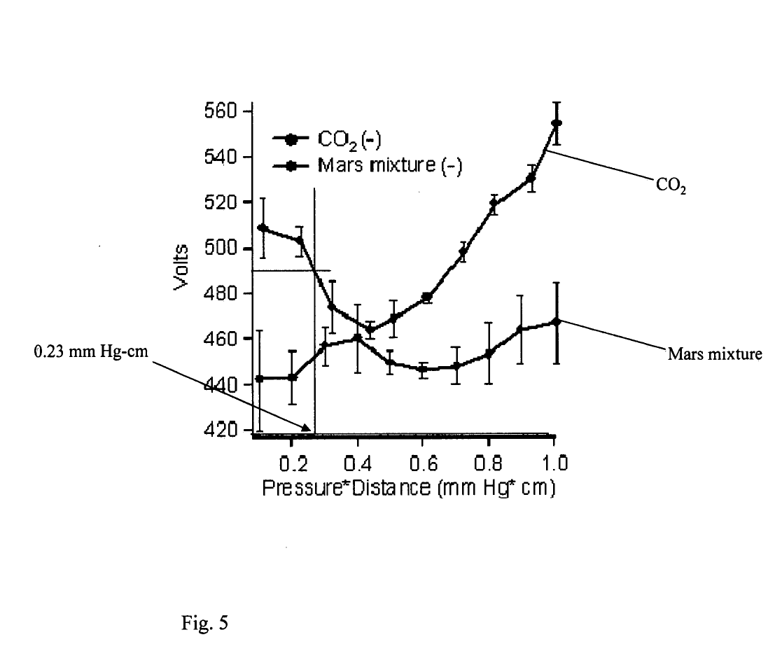

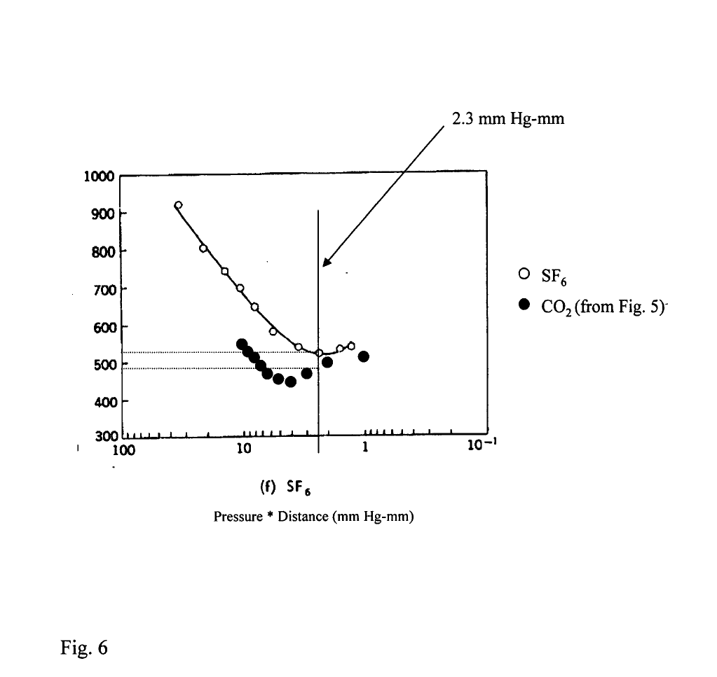

The results summarized in Tables 1 and 2 are at odds with the published high voltage breakdown, or Paschen curves for the two gases. The Paschen curve is a non-linear relationship between the breakdown voltage, i.e. the voltage at which the gas breaks down and current flows between the electrodes, and the product of the gas pressure and the distance between the electrodes. The Paschen curve for carbon dioxide is shown in FIG. 5. FIG. 5 indicates that the breakdown voltage decreases with decreasing pressure×distance product down to a certain value, at which it begins to increase again. This behavior is typical of gases, wherein by reducing the pressure, one reduces the frequency of collisions between the atoms in the gas. Each collision removes kinetic energy from the gas atom which was acquired by acceleration of the charged species in the electric field. When the collision frequency is reduced, the ionized species may more easily acquire sufficient kinetic energy to ionize additional atoms, leading to an avalanche of charged species and breakdown of the gas. The behavior continues until the gas pressure is reduced to a value at which the mean free path is approximately the distance between electrodes. This leads to a minimum value in the Paschen curve, well documented for many gases experimentally.

The data shown in FIG. 5 is taken from a NASA study of breakdown voltages of carbon dioxide and a mixture of gases representing the Martian atmosphere. This reference may be found at the Universal Resource Locator http://empl.ksc.nasa.gov/CurrentResearch/Breakdown/Breakdown.htm, updated May 21, 2003. The CO₂ mixture shown in FIG. 5 is 95.5% carbon dioxide, 2.7% nitrogen, 1.6% argon, 0.13% oxygen and 0.07% carbon monoxide. From FIG. 5, the Paschen minimum for pure carbon dioxide occurs at a pressure×distance product of about 0.4 mm Hg-cm (or 4 mm Hg-mm) and is about 460 volts. However, the exact behavior of the Paschen curve may be substantially influenced by a number of factors, such as the details of the shape of the electrodes and impurities in the gases, as demonstrated by the dramatically different shape of the Paschen curve for the gas mixture.

The Paschen curve for carbon dioxide shown in FIG. 5 may be used to estimate an expected breakdown voltage for the MEMS switch shown in FIGS. 1 and 2. Assuming a gas pressure of about 1 atm (760 mm Hg), and a distance between electrodes of about 3 μm, gives a pressure*distance value of at least about 0.23 mm Hg-cm. According to the Paschen curve shown in FIG. 5, the high voltage breakdown value for this scenario is about 490 volts for CO₂.

FIG. 6 shows a published Paschen curve for SF₆. This data may be found in Technical Note D-1761, Goddard Space Flight Center, page 6, dated June 1963. The units for this plot are in mm Hg-mm, and the x-axis is oriented in the opposite direction from that shown in FIG. 5. For comparison, the data for CO₂ from FIG. 5 is shown superimposed on the SF₆ data from this reference. As shown in FIG. 6, the points corresponding the carbon dioxide lie below those shown for sulfur hexafluoride for all points shown, indicating that carbon dioxide can be expected to have a lower breakdown voltage than carbon dioxide. Accordingly, the breakdown voltage for sulfur hexafluoride may be expected to be at least about ten to thirty percent higher than that of carbon dioxide at low pressure×distance products. For example, the breakdown voltage for sulfur hexafluoride at the design point of 2.3 mm Hg-mm, is about 525 volts, compared to a breakdown voltage of 490 volts for carbon dioxide as shown in FIG. 6. The x-axis location of these points on the plot are identified by the arrow in FIG. 6. This behavior is qualitatively similar to that measured for the gases at much higher pressure×distance products, wherein the performance of sulfur hexafluoride exceeds that of carbon dioxide by about a factor of two (See for example, FIG. 4 of Y. Hoshina et al., EE Proc.-Sci. Meas. Tech., Vol. 153, No. 1, January 2006, page 3).

The data shown in FIGS. 5 and 6 are taken using relatively large gap distances, on the order of millimeters, at low pressure, on the order of millitorr, to measure the breakdown voltages. However, for MEMS devices, the gaps are much smaller, on the order of microns, whereas the gas pressures may be much higher, on the order of an atmosphere. Accordingly, the Paschen curves such as those shown in FIGS. 5 and 6 may not predict the relative performance of insulating gases in MEMS devices. In fact, as shown in Tables 1 and 2 and FIGS. 3 and 4, the performance of carbon dioxide may unexpectedly surpass that of sulfur hexafluoride, in contrast to the predictions of the Paschen curves in FIGS. 5 and 6.

The predicted superior performance of SF₆ compared to other gases at low pressure and large gaps may be based on theoretical modeling which attributes the high breakdown voltage of SF₆ to its unique “quenching” mechanism. That is, for most recognized insulating gases, their dielectric properties are primarily a result of tightly-bound electrons which require a large electric field for ionization. This ionization, once initiated, tends to avalanche and cause electrical breakdown of the gas. However, for electronegative gases such as SF₆, its dielectric properties are attributed to its affinity for taking up electrons, so that even though it is relatively easy to ionize, the charged particles are readily reabsorbed by neighboring SF₆ atoms. It may be the case that at the very small distances in play for MEMS devices, this quenching mechanism is less effective than previously believed, because there are an insufficient number of encounters with the absorbing atoms when the distances become small, as in MEMS devices. In the small distance regime, the breakdown performance of a given gas may instead be largely a function of its interaction with the material of the electrodes, for example, thereby altering the field emission characteristics of the device and thus its breakdown behavior.

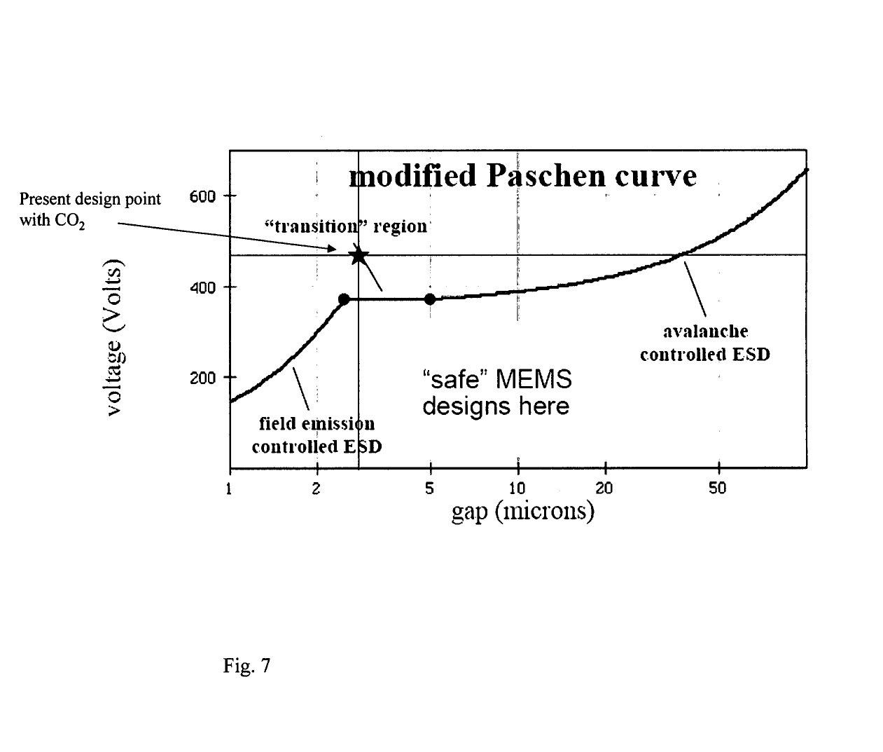

In fact, there are published reports of gases not following the traditional Paschen behavior at small gaps. For example, in Conference Publication 467 of the High Voltage Engineering Symposium 22-27 August, 1999, IEE 1999, pages 1-4 by J.-M. Torres, et al., the authors suggest that gases in general may not follow Paschen curves at small gap distances. Another reference, “Electrical Breakdown Limits for MEMS,” which can be found at the Universal Resource Locator http://www.ece.rochester.edu/courses/ECE234/MEMS_ESD.pdf, also suggests that gases in general may deviate from the Paschen curve at small gap distances. For example, FIG. 7, taken from this reference, shows a schematic illustration of the generalized behavior of gases at small gap spacings, which deviates from the larger-gap values of Paschen curves, at gap spacings beneath about 3 μm. The operating point for the devices discussed with respect to FIGS. 1-4 are shown by the star located on the plot of FIG. 7. As can be seen in FIG. 7, the use of carbon dioxide as the insulating gas in these MEMS devices allows operation well outside the “safe” MEMS design regime indicated in FIG. 7.

Based on these data, all gases may show a drop in breakdown voltage at small gaps relative to the traditional Paschen curve. As shown in FIG. 6, the published literature on breakdown voltage values in SF6 and CO2 at the gap and voltage of interest indicates that SF6 should have a higher breakdown voltage than CO2. However, as shown in FIGS. 3 and 4, CO₂ surprisingly has higher breakdown voltage than sulfur hexafluoride as measured on a MEMS switch gap. Given that deviations from the Paschen curve at small gaps have been suggested in several references, the experimental evidence of FIG. 3 and 4 becomes credible, in spite of other published data (FIG. 6) to the contrary. The discrepancy probably lies in the experimental setup used to calculate the data shown in FIG. 6. Typically, the breakdown voltage is measured with a low gas pressures (milliTorr range) and large (millimeter scale) gaps. The product of pressure times gap length for these experiment is the same as with Torr-level pressure and micrometer scale gaps, with scalability to extremely small gaps incorrectly assumed to be valid. There is no previously published data that claims that CO2 is a better insulating gas than SF6 in any gap size range. As illustrated by FIG. 6, all published data indicate that sulfur hexafluoride should perform better than carbon dioxide in all gap size regimes. The experimental data shown in FIGS. 3 and 4 therefore represent a novel insight into the dielectric properties of CO2 and SF6.

In addition, carbon dioxide may have other advantageous properties relative to sulfur hexafluoride. For example, the MEMS switch shown in FIG. 1 requires dielectric tethers 150 and 250, such as photopatternable SU-8, developed by IBM corporation of Armonk, N.Y., to couple the cantilevered drive circuits 120 and 220 to the passive cantilevered beams 110 and 210. Carbon dioxide may be less reactive than sulfur hexafluoride, so that less corrosion of the dielectric tethers occurs. In addition, sulfur hexafluoride is known to be a particularly damaging greenhouse gas, having a global warming potential many orders of magnitude higher than carbon dioxide as published in Climate Change 2001: Group 1: Intergovernmental Panel on Climate Change, page 4.

What follows is a description of one exemplary method for manufacturing the MEMS hermetic switch device 1000 with carbon dioxide environment shown in FIG. 2.

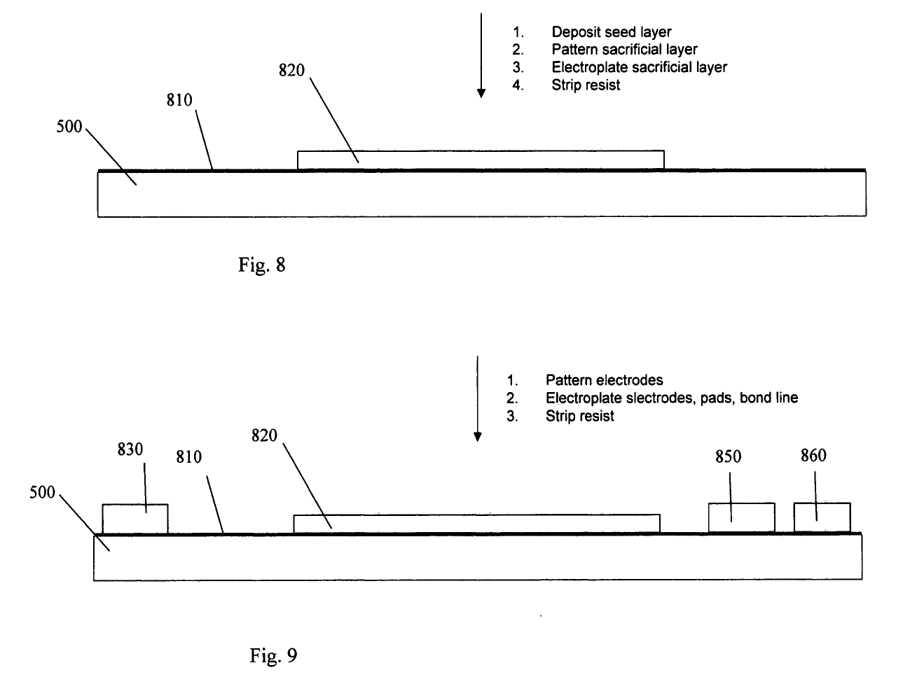

FIG. 8 illustrates a first exemplary step in the fabrication of the MEMS device 800. The process may begin with the deposition of a seed layer 810 for later plating of a MEMS switch moveable member 840, over the substrate 500. The seed layer 810 may be chromium (Cr) and gold (Au), deposited by chemical vapor deposition (CVD) or sputter deposition, for example, to a thickness of 100-200 nm. Photoresist may then be deposited over the seed layer 810, and patterned by exposure through a mask. A sacrificial layer 820, such as copper, may then be electroplated over the seed layer. The photoresist may then be stripped from the substrate 500.

A second exemplary step in fabricating the MEMS device 800 is illustrated in FIG. 9. In FIG. 9, the substrate 500 is again covered with photoresist, which is exposed through a mask with features corresponding to a gold bonding ring 830 and 850, and an external access pad 860. The pads 830, 850 and 860, may subsequently be plated in the appropriate areas. The gold bonding pads 830 and 850 may eventually form a portion of the seal which will bond the cap layer 400 to the substrate 500. The external access pad 860 may provide a pad for accessing the MEMS device 800 electrically, from outside the hermetically sealed structure.

The gold bonding pads 830, 850 and 860 may then be electroplated in the areas exposed by the photoresist, to form gold bonding pads 830, 850 and 860 and any other gold structures needed. The photoresist is then stripped from the substrate 500. The thickness of the gold bonding pads 830, 850 and 860 may be, for example, 1 μm.

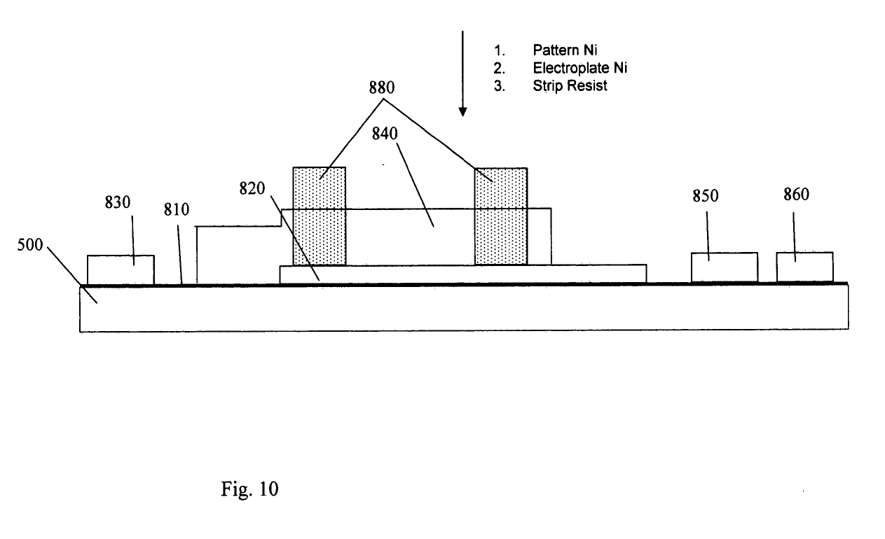

FIG. 10 illustrates a third step in fabricating the MEMS device 800. In FIG. 10, photoresist is once again deposited over the substrate 500, and patterned according to the features in a mask. The exposed portions of the photoresist are then dissolved as before, exposing the appropriate areas of the seed layer. The exposed seed layer 810 may then be electroplated with nickel or other appropriately selected material, to form a moveable member 840 of the MEMS device 800.

The moveable member 840 may be, for example, a cantilevered arm which responds to an electrostatic force generated between two conducting plates formed between the substrate and moveable member 840. Alternatively, the moveable member 840 may be the cantilevered beam of an accelerometer. Since the details of such devices are not required for the understanding of this invention, they are not further described or depicted in FIG. 10. If the moveable member 840 corresponds to cantilevered drive circuit 120 or 220 of FIG. 1, the moveable member 840 may additionally be covered with a layer of photopatternable polymer 880 such as SU-8, which may then be exposed and developed to form dielectric tethers 150 and 250, coupling the cantilevered drive circuits 120 and 220 to the passive cantilevered beams 110 and 210, respectively.

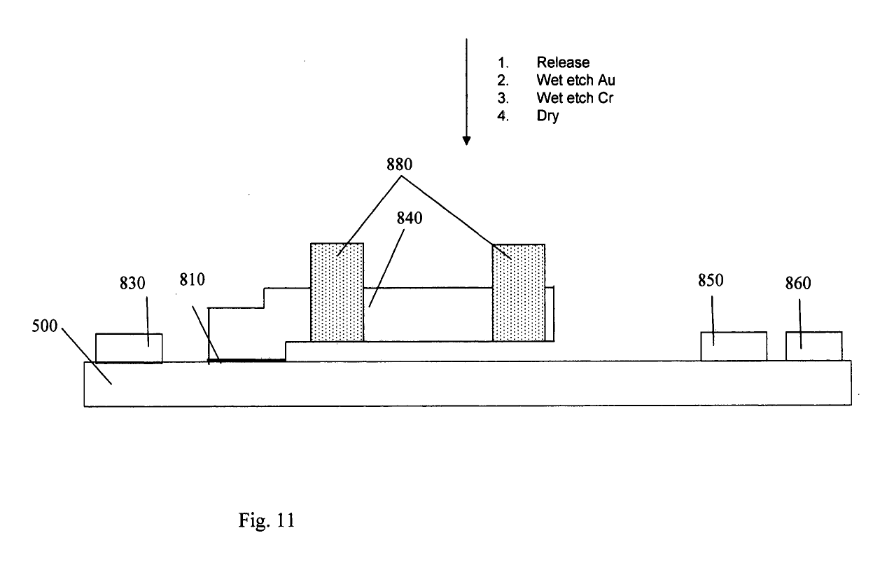

FIG. 11 illustrates the final step in the fabrication of the MEMS device 800. In this step, the moveable member 840 may be released by etching the sacrificial copper layer 820. Suitable etchants may be, for example, an isotropic etch using an ammonia-based Cu etchant. The Cr and Au seed layer 810 is then also etched using, for example, a wet etchant such as iodine/iodide for the Au and permanganate for the Cr, to expose the SiO₂ surface of the substrate 500. The substrate 500 and MEMS device 800 may then be rinsed and dried.

It should be understood that the external access pad 860 may be used for electrical access to the MEMS device 800, such as to supply a signal to the MEMS device 800, or to supply a voltage to an electrostatic plate in order to activate the switch, for example. The external access pad 860 may be located outside the bond line which will be formed upon completion of the cap wafer 400 and substrate 500 assembly, as described further below.

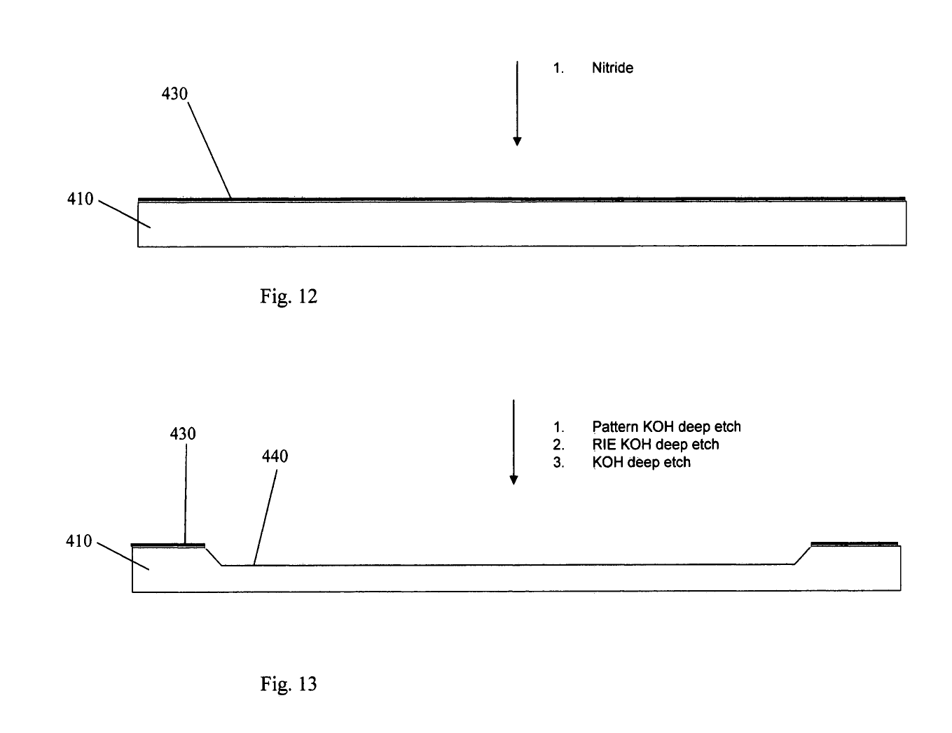

The process description now turns to the fabrication of the cap wafer 400, and its installation over the substrate 500. The process described is applicable to a silicon cap wafer. If other substrate materials are used, such as glass or ceramic or other metals, the process may be modified accordingly. As illustrated in FIG. 12, the cap wafer 400 may be a silicon substrate 410 which is first covered with a silicon nitride (Si₂N₃) layer 430. The silicon nitride layer 430 may then be patterned by reactive ion etching (RIE), for example, to form a hard mask for a later wet etch.

As shown in FIG. 13, a deep etch is then performed into the silicon substrate 410 through the silicon nitride layer 430 on the cap wafer 400, to provide clearance for the moveable arm 840 of the MEMS device 800. The deep etch may be performed by, for example, exposure to a potassium hydroxide etching solution. The etch depth may be, for example, several hundred μm deep.

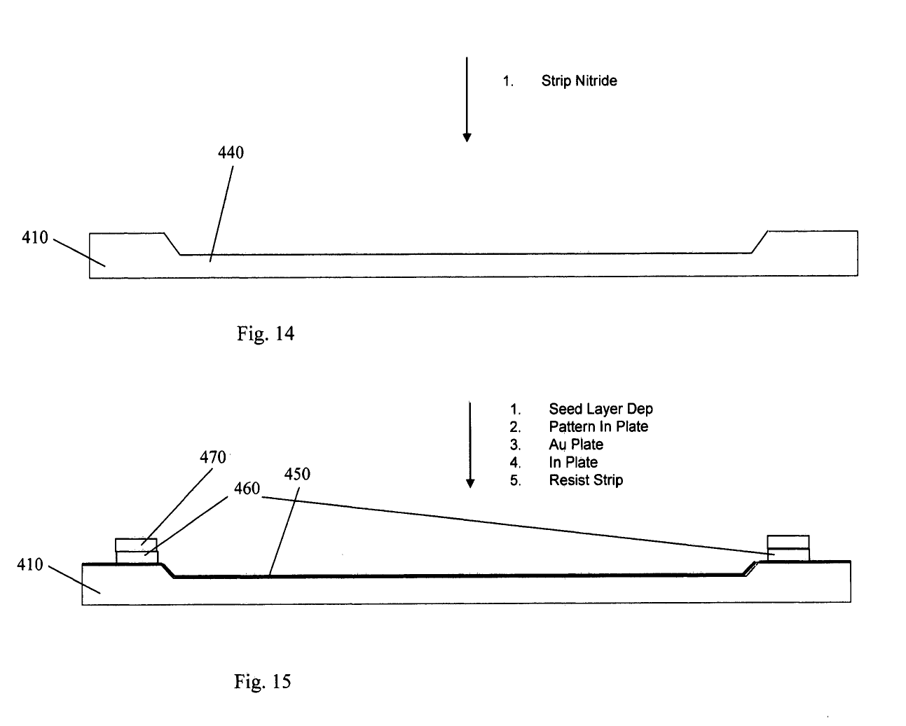

FIG. 14 illustrates a third step in the fabrication of cap wafer 400. In FIG. 14, the nitride is stripped, leaving the bare surface of the cap wafer 400.

FIG. 15 illustrates a fourth step in the fabrication of the cap wafer 400. In FIG. 14, the cap wafer 400 is covered with a deposited seed layer 450, such as Cr/Au. The seed layer 450 is then covered with photoresist, which is patterned by exposure through a mask. The mask has features which correspond to the locations of the bond ring which will participate in the alloy bond to the substrate 500. These locations are identified by reference number 460. The photoresist is dissolved by a suitable solvent in the region 460, to expose the seed layer 450 beneath the photoresist. A gold (Au) layer 460 is then electroplated or sputtered into these regions to a thickness of about 1 μm. After the gold is plated or sputtered, a layer 470 of indium (In) is electroplated into these same regions, to a thickness of about 3 μm to about 6 μm. The relative thicknesses of the gold to the indium may be important to control, as the proper alloy stoichiometry is about 2 atoms of indium to every atom of gold, to form an alloy AuIn, and preferably to form AuIn₂. Since the molar volume of indium is about 50% greater than gold, a combined gold thickness of both layers 460 and 830 of about 1 μm to about 2 μm may be approximately correct to form the AuIn₂ alloy. This thickness of gold may provide enough gold material for forming the alloy, while still leaving a thin film of gold on the surface of the seed layer 450, to provide good adhesion to the seed layer 450.

It may be important for metallization pads 460 and 830 to be wider in extent than the plated indium layer 470. The excess area may allow the indium to flow outward somewhat upon melting, without escaping the bond region, while simultaneously providing for the necessary Au/In ratios cited above.

The cap wafer 400 may now be assembled with the substrate 500 in the preferred gas environment of carbon dioxide to form the encapsulated MEMS structure 2000. The cap wafer 400 may be bonded to the substrate 500 by forming an alloy bond between the gold layer 460 and indium layer 470 located on the cap wafer 400, and the gold layer 830 located on the substrate 500.

The cap wafer 400 and substrate 500 with the MEMS switch 800 may first be placed in a chamber which is evacuated and then filled with substantially pure carbon dioxide CO₂, at a pressure of between about 0.2 and about 4 atmospheres. The term “substantially pure” carbon dioxide should be understood to mean that carbon dioxide makes up at least 90% of the gaseous material, and more preferably at least 95% of the gaseous material, the remainder being impurity gases such as nitrogen, water vapor or oxygen. The substantially pure carbon dioxide is then sealed within the encapsulated MEMS structure 2000 by sealing the cap wafer 400 to the substrate 500 with the alloy bond formed by layers 460, 470 and 830.

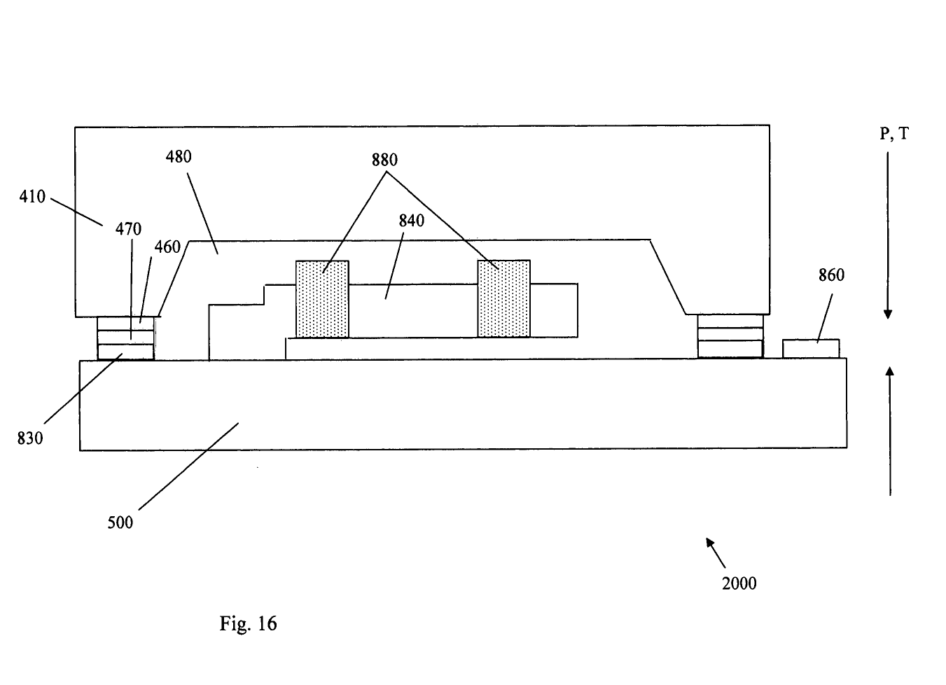

To form the alloy bond between layers 460, 470 and 830, the cap wafer 410 may be applied to the substrate 500 under pressure and at elevated temperature, as shown in FIG. 16. For example, the pressure applied between the cap wafer 410 and the substrate 500 may be about 0.5 to 4.5 atmospheres, and at an elevated temperature of about 160-180 degrees centigrade. This temperature exceeds the melting point of the indium (about 156 degrees centigrade), such that the indium flows into and forms an alloy with the gold. As mentioned above, the preferred stoichiometry of the alloy may be about 2 indium atoms per one gold atom, to form AuInₓ. In contrast to the low melting point of the indium metal, the melting point of the AuIn₂ alloy is about 541 degrees centigrade. Therefore, although the alloy is formed at a relatively low temperature, the durability of the alloy bond is outstanding even at several hundred degrees centigrade. The bond is therefore compatible with processes which deposit vulnerable materials, such as metals, on the surfaces and in the devices. These vulnerable materials may not be able to survive temperatures in excess of about 200 degrees centigrade, without oxidizing or degrading.

After assembling and bonding the cap wafer 410 with the substrate 500, the assembly may be diced to separate the individual encapsulated MEMS structures 2000, as shown in FIG. 16. The devices may be singulated using, for example, the methods described in greater detail in U.S. patent application Ser. No. 11/434,768 (Attorney Docket No. IMT-Singulate), incorporated by reference herein in its entirety. Alternatively, the devices may be separated using sawing, grinding or etching, for example.

While the systems and methods described here use a gold/indium alloy to seal the MEMS switch, it should be understood that the encapsulated MEMS structure 2000 may use any of a number of alternative sealing methodologies. For example, the seal may also be formed using an Au/Si alloy, glass flit, solder, or low-outgassing epoxy which is impermeable to the carbon dioxide insulating gas.

While various details have been described in conjunction with the exemplary implementations outlined above, various alternatives, modifications, variations, improvements, and/or substantial equivalents, whether known or that are or may be presently unforeseen, may become apparent upon reviewing the foregoing disclosure. For example, an exemplary MEMS switch is described as an application for the carbon dioxide gas environment described herein. However, it should be understood that the MEMS switch is exemplary only, and that the carbon dioxide environment may be applied to any of a wide variety of other MEMS structures or devices. Accordingly, the exemplary implementations set forth above, are intended to be illustrative, not limiting.

What is claimed is:

1. An encapsulated MEMS device, comprising:
at least a portion of a lid wafer with at least one device cavity formed therein;
at least a portion of a device wafer supporting at least one MEMS device;
a hermetic seal coupling the lid wafer portion to the device wafer portion; and
a preferred environment sealed in the at least one device cavity by the hermetic seal, wherein the preferred environment comprises substantially pure carbon dioxide.

2. The encapsulated MEMS device of claim 1, wherein the carbon dioxide preferred environment has a pressure of between about 0.2 atm and about 4 atm.

3. The encapsulated MEMS device of claim 1, wherein a distance between a high voltage terminal in the device and a low voltage terminal in the at least one MEMS device is less than about 10 μm.

4. The encapsulated MEMS device of claim 1, wherein the at least one MEMS device further comprises a thermally actuated cantilevered beam.

5. The encapsulated MEMS device of claim 4, wherein the thermally actuated cantilevered beam comprises a portion of a conductive circuit.

6. The encapsulated MEMS device of claim 5, wherein the at least one MEMS device further comprises a passive cantilevered beam which is tethered to the thermally actuated cantilevered beam by at least one dielectric tether.

7. The encapsulated MEMS device of claim 6, wherein the at least one dielectric tether comprises SU-8.

8. The encapsulated MEMS device of claim 1, wherein the at least one MEMS device further comprises at least one of a cantilever, an accelerometer, an actuator, a photonic crystal, a switch, a resonator, an infrared emitter and an infrared detector.

9. The encapsulated MEMS device of claim 1, wherein the hermetic seal comprises a metal alloy.

10. The encapsulated MEMS device of claim 9, wherein the metal alloy comprises AuInₓ, wherein x is about 2.

11. A method for forming an encapsulated MEMS device, comprising:
forming at least one device cavity in a lid wafer;
forming at least one MEMS device on a device wafer; and
coupling the lid wafer to the device wafer in a preferred environment, the preferred environment comprising substantially pure carbon dioxide.

12. The method of claim 11, further comprising:
sealing the MEMS device within the preferred environment with a hermetic seal.

13. The method of claim 11, wherein forming the at least one MEMS device on the device wafer comprises forming a thermally actuated cantilevered beam on the device wafer.

14. The method of claim 13, wherein forming the MEMS device on the device wafer further comprises:
forming a cantilevered passive beam on the device wafer; and
tethering the cantilevered passive beam to the thermally actuated cantilevered beam with a dielectric tether.

15. The method of claim 11, further comprising:
separating the at least one MEMS device formed on the device wafer from other portions of the device wafer by at least one of sawing, grinding and etching.

16. The method of claim 12, wherein sealing the MEMS device within the preferred environment with the hermetic seal comprises heating at least one component of a metal alloy deposited on at least one of the device wafer and the lid wafer and forming a metal alloy bond with at least one other component of the metal alloy.

17. The method of claim 11, wherein forming the at least one MEMS device comprises forming the at least one MEMS device with a distance between a high voltage terminal of the device and a low voltage terminal of the device is less than about 10 μm.

18. The method of claim 14, wherein tethering the cantilevered passive beam to the thermally actuated cantilevered beam comprises:
covering the cantilevered passive beam and the thermally actuated cantilevered beam with photoresist;
exposing the photoresist; and
developing the photoresist such that is covers only a portion of the cantilevered passive beam and the thermally actuated cantilevered beam.

19. The method of claim 11, wherein forming the at least one MEMS device on the device wafer comprises forming at least one of an accelerometer, an actuator, a switch, a resonator, a photonic crystal, an infrared emitter and an infrared detector on the device wafer.

20. An apparatus for forming an encapsulated MEMS device, comprising:
means for forming a device cavity in a lid wafer;
means for forming at least one MEMS device on a device wafer; and
means for coupling the lid wafer to the device wafer in a preferred environment, the preferred environment comprising substantially pure carbon dioxide.
